(19) United States
(12) Patent Application Publication
(10) Pub. No.: US 2008/0174015 A1
(43) Pub. Date: Jul. 24, 2008

(54) REMOVAL OF ETCHING PROCESS RESIDUAL IN SEMICONDUCTOR FABRICATION

(76) Inventors: Russell Thomas Herrin, Essex Junction, VT (US); Peter James Lindgren, Essex Junction, VT (US); Anthony Kendall Stamper, Williston, VT (US)

Correspondence Address: SCHMEISER, OLSEN & WATTS, 22 CENTURY HILL DRIVE, SUITE 302, LATHAM, NY, 12110, US

(21) Appl. No.: 11/626,054

(22) Filed: Jan. 23, 2007

(51) Int. Cl. H01L 21/768; H01L 23/522

(52) U.S. Cl. 257/741; 438/620; 257/E21.585; 257/E23.145

(57) ABSTRACT

A semiconductor structure and methods for forming the same. A semiconductor fabrication method includes steps of providing a structure. A structure includes (a) a dielectric layer, (b) a first electrically conductive region buried in the dielectric layer, wherein the first electrically conductive region comprises a first electrically conductive material, and (c) a second electrically conductive region buried in the dielectric layer, wherein the second electrically conductive region comprises a second electrically conductive material being different from the first electrically conductive material. The method further includes the steps of creating a first hole and a second hole in the dielectric layer resulting in the first and second electrically conductive regions being exposed to a surrounding ambient through the first and second holes, respectively. Then, the method further includes the steps of introducing a basic solvent to bottom walls and side walls of the first and second holes.

### FIELD OF THE INVENTION

The present invention relates generally to semiconductor fabrication, and more specifically, to removal of etching process residual in semiconductor fabrication.

### BACKGROUND OF THE INVENTION

In a conventional semiconductor fabrication process, vias are formed to provide electrical access to the underlying metal lines. The vias are created by a plasma etching process which leaves residual on side walls and bottom walls of the via holes. Therefore, there is a need for a process to remove the residual before the via holes are filled with an electrically conductive material to form the vias.

### SUMMARY OF THE INVENTION

The present invention provides a structure formation method, comprising providing a structure which includes (a) a dielectric layer, (b) a first electrically conductive region buried in the dielectric layer, wherein the first electrically conductive region comprises a first electrically conductive material, and (c) a second electrically conductive region buried in the dielectric layer, wherein the second electrically conductive region comprises a second electrically conductive material being different from the first electrically conductive material; creating a first hole and a second hole in the dielectric layer resulting in the first and second electrically conductive regions being exposed to a surrounding ambient through the first and second holes, respectively; and introducing a basic solvent to bottom walls and side walls of the first and second holes resulting in a removal of polymer residues on the bottom walls and side walls of the first and second holes.

The present invention provides a process to remove the residual before the via holes are filled with an electrically conductive material to form the vias.

### BRIEF DESCRIPTION OF THE DRAWINGS

FIGS. 1A-1M illustrate (cross-section views) a fabrication method for forming a semiconductor structure, in accordance with embodiments of the present invention.

### DETAILED DESCRIPTION OF THE INVENTION

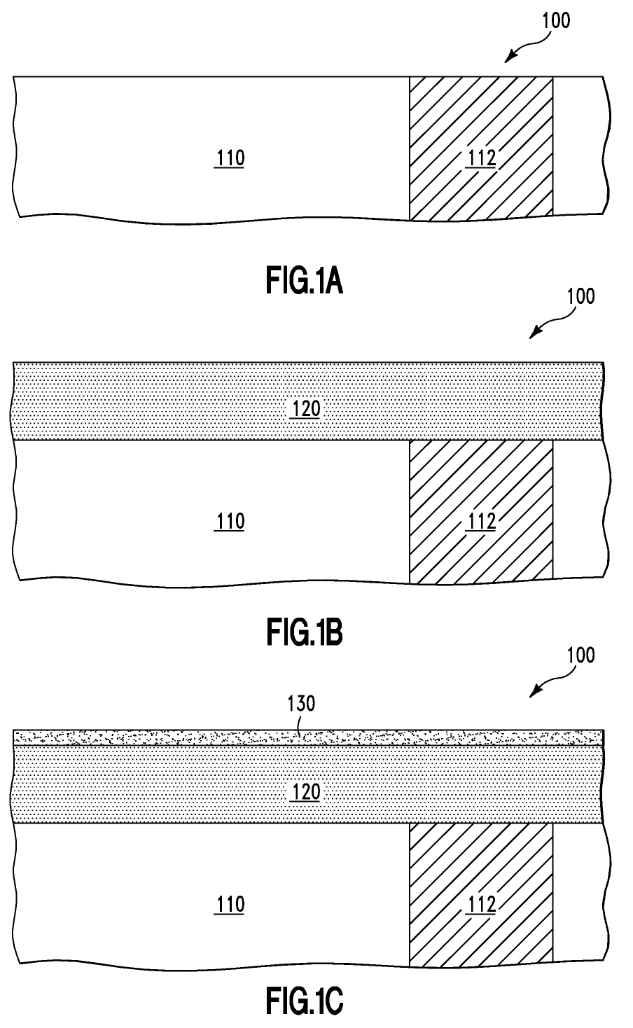

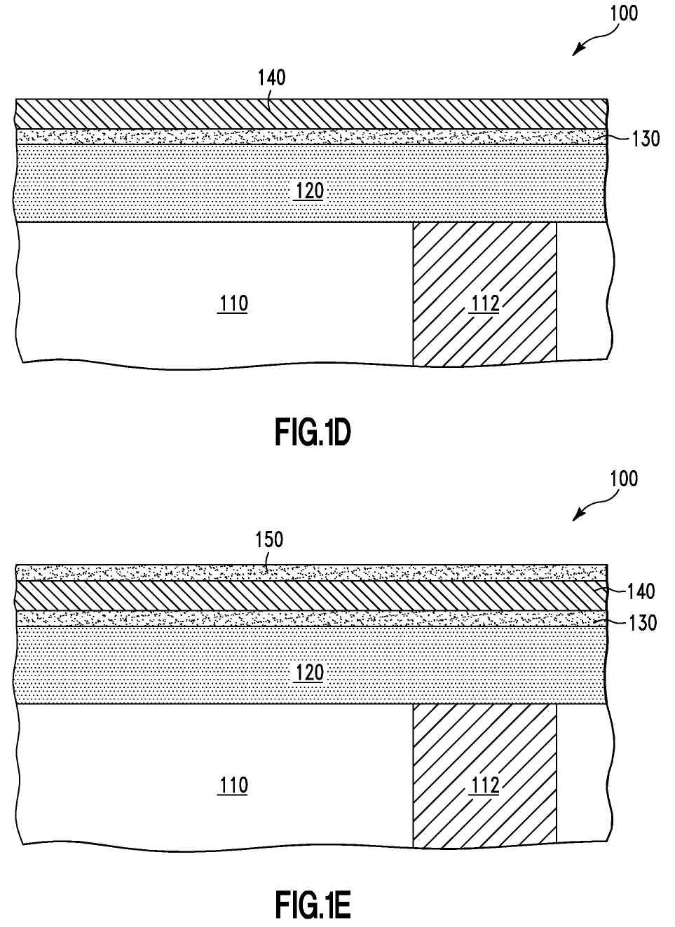

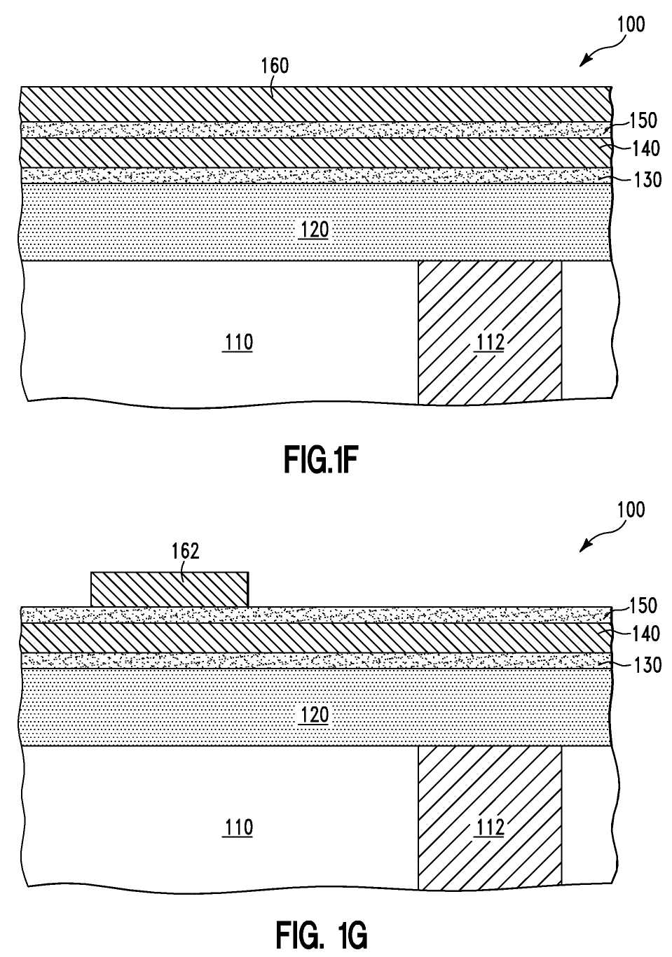

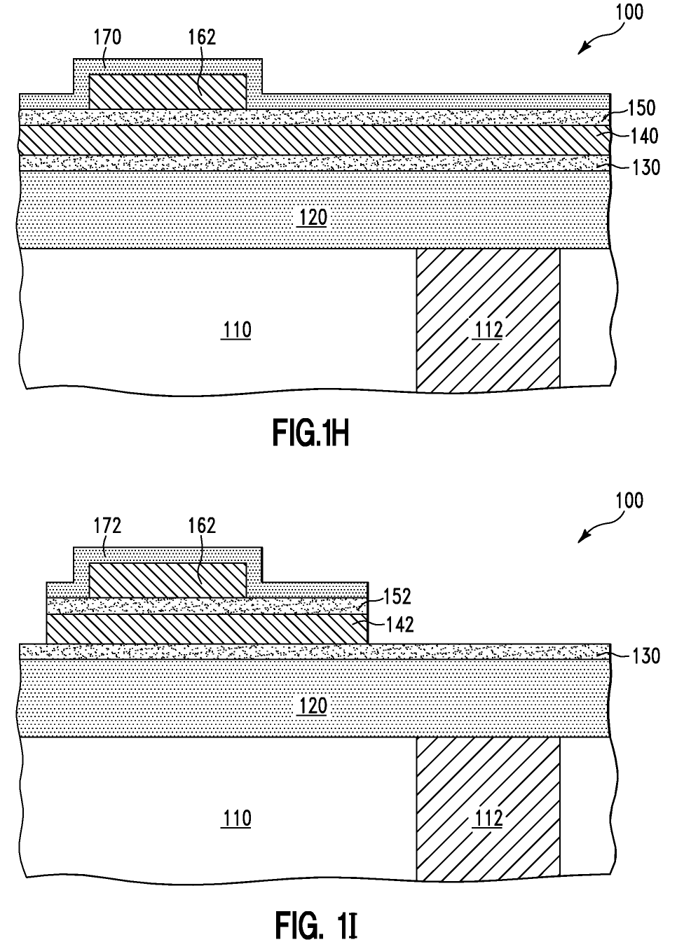

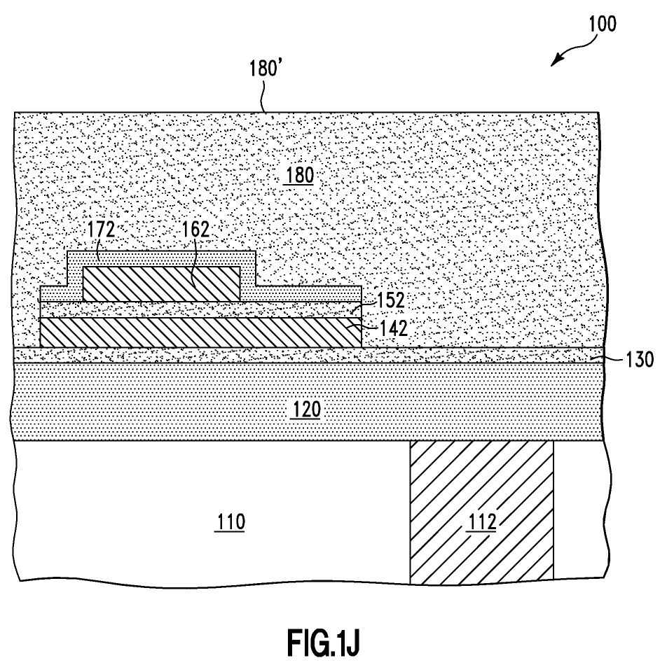

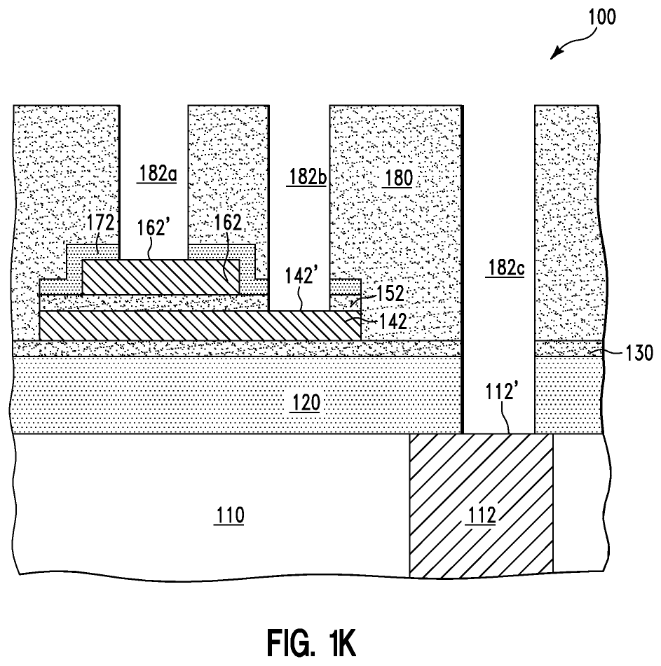

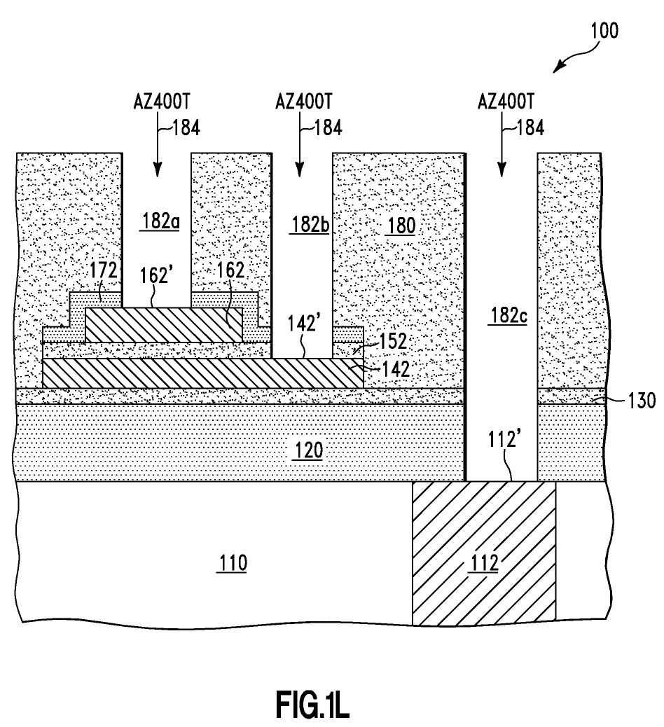

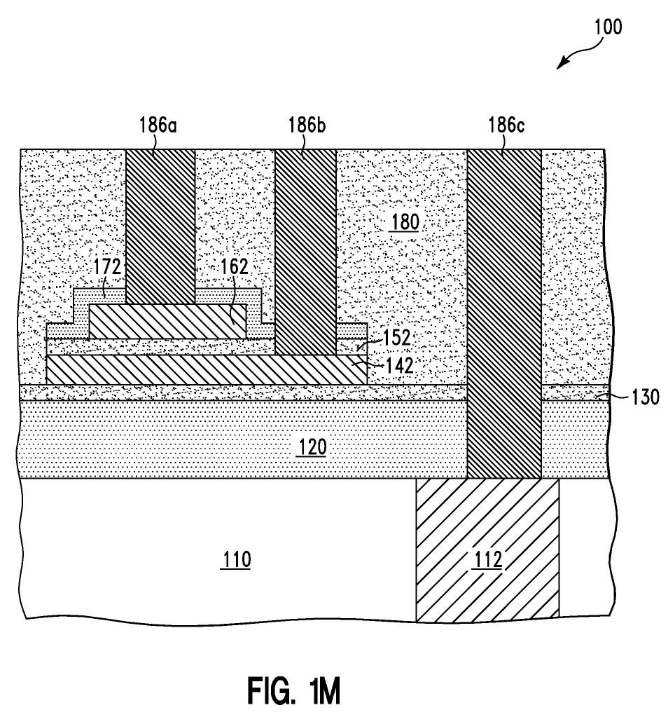

FIGS. 1A-1M illustrate (cross-section views) a fabrication method for forming a semiconductor structure 100, in accordance with embodiments of the present invention. More specifically, with reference to FIG. 1A, in one embodiment, the fabrication of the semiconductor structure 100 starts out with an ILD (Interlevel Dielectric Layer) layer 110. Illustratively, the ILD layer 110 can comprise silicon dioxide or a low-K (i.e., K<3) material, wherein K is the dielectric constant. In one embodiment, the ILD layer 110 is formed on top of a device layer of a semiconductor integrated circuit (not shown) which is omitted from this and later figures for simplicity. The device layer is a layer on top of a silicon wafer (not shown) where devices such as transistors are formed.

Next, in one embodiment, a metal line 112 is formed in the ILD layer 110 by using a conventional damascene method. In one embodiment, the metal line 112 comprises copper (Cu). In one embodiment, the metal line 112 is electrically coupled to devices (not shown) of the underlying device layer.

Next, with reference to FIG. 1B, in one embodiment, a first cap layer 120 is formed on top of the entire structure 100 of FIG. 1A. In one embodiment, the first cap layer 120 is formed by CVD (Chemical Vapor Deposition) of a dielectric material on top of the ILD layer 110 and the metal line 112. In one embodiment, the first cap layer 120 comprises silicon carbide (SiC), silicon nitride (SiN), or silicon carbon nitride (SiCN).

Next, with reference to FIG. 1C, in one embodiment, a dielectric layer 130 is formed on top of the entire structure 100 of FIG. 1B. In one embodiment, the dielectric layer 130 comprises silicon dioxide. In one embodiment, the dielectric layer 130 is formed by CVD of silicon dioxide on top of the first cap layer 120.

Next, with reference to FIG. 1D, in one embodiment, a bottom electrically conductive layer 140 is formed on top of the entire structure 100 of FIG. 1C. In one embodiment, the bottom electrically conductive layer 140 is formed by CVD or PVD of an electrically conductive material on top of the dielectric layer 130. In one embodiment, the bottom electrically conductive layer 140 comprises aluminum (Al), tungsten (W), tantalum nitride (TaN), or any refractory metal/alloy, or any other electrically conductive material.

Next, with reference to FIG. 1E, in one embodiment, a dielectric layer 150 is formed on top of the entire structure 100 of FIG. 1D. In one embodiment, the dielectric layer 150 is formed by CVD of a dielectric material on top of the bottom electrically conductive layer 140. In one embodiment, the dielectric layer 150 comprises silicon dioxide or a high K dielectric material.

Next, with reference to FIG. 1F, in one embodiment, a top electrically conductive layer 160 is formed on top of the entire structure 100 of FIG. 1E. In one embodiment, the top electrically conductive layer 160 is formed by CVD or PVD of an electrically conductive material on top of the dielectric layer 150. In one embodiment, the top electrically conductive layer 160 comprises aluminum (Al), tungsten (W), tantalum nitride (TaN), or any refractory metal/alloy, or any other electrically conductive material. It should be noted that the dielectric layer 150 electrically insulates the top electrically conductive layer 160 from the bottom electrically conductive layer 140.

Next, in one embodiment, the top electrically conductive layer 160 is patterned resulting in a top plate 162 as shown in FIG. 1G. More specifically, the patterning process to form the top plate 162 can involve photo-lithography and then RIE (Reactive Ion Etching) etching. In one embodiment, the etching process to form the top plate 162 essentially stops at the dielectric layer 150.

Next, with reference to FIG. 1H, in one embodiment, a second cap layer 170 is formed on top of the entire structure 100 of FIG. 1G. In one embodiment, the second cap layer 170 is formed by CVD of a dielectric material on top of the entire structure 100 of FIG. 1G. In one embodiment, the second cap layer 170 comprises silicon carbide (SiC), silicon nitride (SiN), or silicon carbon nitride (SiCN).

Next, with reference to FIG. 1I, in one embodiment, a MIM (Metal-Insulator-Metal) cap layer 172, a MIM dielectric layer 152, and a MIM bottom plate 142 are created from the second cap layer 170, the dielectric layer 150, and the bottom electrically conductive layer 140, respectively, of FIG. 1H. Illustratively, the step of forming the MIM cap layer 172, the MIM dielectric layer 152, and the MIM bottom plate 142 can involve photo-lithography and then RIE etching. In one embodiment, the etching process to form the MIM cap layer 172, the MIM dielectric layer 152, and the MIM bottom plate 142 is performed through the second cap layer 170, the dielectric layer 150, and the bottom electrically conductive layer 140, respectively, of FIG. 1H, and essentially stops at the dielectric layer 130. It should be noted that the MIM bottom plate 142, the MIM dielectric layer 152, and the top plate 162 (also called a MIM top plate 162) can be collectively referred to as a MIM capacitor 142+152+162.

Next, with reference to FIG. 1J, in one embodiment, a dielectric layer 180 is formed on top of the entire structure 100 of FIG. 1I. In one embodiment, the dielectric layer 180 is formed by CVD of a dielectric material on top of the entire structure 100 of FIG. 1I, and then a top surface 180′ of the dielectric layer 180 is planarized by, illustratively, a CMP (Chemical Mechanical Polishing) step. In one embodiment, the dielectric layer 180 comprises silicon dioxide.

Next, with reference to FIG. 1K, in one embodiment, holes 182a, 182b, and 182c are formed in the dielectric layer 180, the MIM cap layer 172, and the MIM dielectric layer 152. Illustratively, the holes 182a, 182b, and 182c are formed by using a conventional lithography and etching process. In one embodiment, the etching process to form the hole 182a essentially stops at the MIM top plate 162, and exposes a top surface 162′ of the MIM top plate 162 to the surrounding ambient through the hole 182a. In one embodiment, the etching process to form the hole 182b essentially stops at the MIM bottom plate 142, and exposes a top surface 142′ of the MIM bottom plate 142 to the surrounding ambient through the hole 182b. In one embodiment, the etching process to form the hole 182c essentially stops at the metal line 112, and exposes a top surface 112′ of the metal line 112 to the surrounding ambient through the hole 182c. It should be noted that the holes 182a and 182c are formed simultaneously because the process to form the holes 182a and 182c is performed etching through the two materials silicon dioxide and silicon nitride as shown in FIG. 1K. It should be noted that the etching process to form the holes 182a, 182b, and 182c creates residual organic polymers (not shown for simplicity) on side walls and bottom walls of the holes 182a, 182b, and 182c and these residual organic polymers are harmful to the final product (not shown).

Next, with reference to FIG. 1L, in one embodiment, the residual organic polymers in the holes 182a, 182b, and 182c are removed by AZ400T. This removal step is represented by arrows 184 and hereafter is referred to as a removal step 184.

AZ400T was originally produced by Clariant. AZ400T is now known under another name “0.175 N Stripper” and can be purchased from Ultra Pure Solutions. In one embodiment, AZ400T is a mixture of (i) 0.175 N tetramethyl ammonium hydroxide (TMAH), (ii) N-Methyl Pyrrolidone (NMP) at about 74% in volume, and (iii) propylene glycol at about 24% in volume.

In one embodiment, AZ400T being in fluid state is heated to 80° C. and then applied to the side walls and bottom walls of the holes 182a, 182b, and 182c at atmospheric pressure so as to remove organic residues there.

In one embodiment, the MIM bottom plate 142 and the MIM top plate 162 comprise aluminum (Al), tungsten (W), tantalum nitride (TaN), or any refractory metal/alloy, or any other electrically conductive material, whereas the metal line 112 comprises copper (Cu). In this case, AZ400T can be applied to the side walls and bottom walls of the holes 182a, 182b, and 182c so as to remove organic residues there without chemically reacting with any of the materials of the metal line 112, the MIM bottom plate 142, and the MIM top plate 162.

In one embodiment, the metal line 112 comprises copper whereas either the MIM bottom plate 142 or the MIM top plate 162 comprise aluminum. In this case, AZ400T can be applied to the side walls and bottom walls of the holes 182a, 182b, and 182c so as to remove organic residues there without chemically reacting with any of the exposed copper and aluminum.

Next, in one embodiment, the holes 182a, 182b, and 182c are filled with an electrically conductive material so as to form vias 186a, 186b, and 186c, respectively, resulting in the structure 100 of FIG. 1M. In one embodiment, with reference to FIGS. 1L and 1M, the vias 186a, 186b, and 186c are formed by depositing the electrically conductive material on top of the entire structure 100 of FIG. 1L (including in the holes 182a, 182b, and 182c), and then polishing by a CMP step to remove excessive material outside the holes 182a, 182b, and 182c. As a result, the vias 186a, 186b, and 186c are electrically coupled to the MIM top plate 162, the MIM bottom plate 142, and the metal line 112, respectively. In one embodiment, the electrically conductive material used to form the vias 186a, 186b, and 186c is copper. In one embodiment, before the formation of the vias 186a, 186b, and 186c, thin diffusion barrier liner layers (not shown) is formed on side walls and bottom walls of the holes 182a, 182b, and 182c of FIG. 1L. In one embodiment, the thin diffusion barrier liner layers comprise tantalum nitride. As a result, the thin diffusion barrier liner layers prevent copper atoms of the vias 186a, 186b, and 186c from diffusing into the surrounding dielectric environment (not shown). In an alternative embodiment, the electrically conductive material used to form the vias 186a, 186b, and 186c is tungsten (W). In this alternative embodiment, the diffusion barrier liner layers should be made of Ti/TiN.

Next, additional conventional fabrication steps are performed on the structure 100 of FIG. 1M so as to form the final product (not shown).

In one embodiment, in general, after a plasma etch process, AZ400T is used to remove any resulting residual organic polymers on a wafer (not shown). Moreover, in one embodiment, after a plasma resist strip process, AZ400T is used to remove any resulting residual organic polymers on a wafer (not shown).

In the embodiments described above, AZ400T is used to remove the residual organic polymers (not shown) on side walls and bottom walls of the holes 182a, 182b, and 182c of FIG. 1L. In general, a basic (non-acidic) photoresist stripping solvent or a solvent containing TMAH can be used to remove the residual organic polymers (not shown) on side walls and bottom walls of the holes 182a, 182b, and 182c of FIG. 1L.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

1. A structure formation method, comprising:
providing a structure which includes:
(a) a dielectric layer,
(b) a first electrically conductive region buried in the dielectric layer, wherein the first electrically conductive region comprises a first electrically conductive material, and
(c) a second electrically conductive region buried in the dielectric layer, wherein the second electrically conductive region comprises a second electrically conductive material being different from the first electrically conductive material;
creating a first hole and a second hole simultaneously in the dielectric layer resulting in the first and second electrically conductive regions being exposed to a surrounding ambient through the first and second holes, respectively; and
introducing a basic solvent to bottom walls and side walls of the first and second holes resulting in a removal of polymer residues on the bottom walls and side walls of the first and second holes.

2. The method of claim 1, wherein the basic solvent comprises tetramethyl ammonium hydroxide (TMAH).

3. The method of claim 2, wherein the basic solvent further comprises N-Methyl Pyrrolidone (NMP) and propylene glycol.

4. The method of claim 1,
wherein said creating the first hole and the second hole comprises creating the first hole and creating the second hole,
wherein said creating the first hole comprises:
removing a first dielectric portion of the dielectric layer, and
after said removing the first dielectric portion is performed, removing a second dielectric portion of the dielectric layer resulting in the first hole,
wherein said creating the second hole comprises:
removing a third dielectric portion of the dielectric layer, and
after said removing the third dielectric portion is performed, removing a fourth dielectric portion of the dielectric layer resulting in the second hole,
wherein both the first and third dielectric portions comprise a first dielectric material, and
wherein both the second and fourth dielectric portions comprise a second dielectric material different than the first dielectric material.

5. The method of claim 4,
wherein the first dielectric material comprises silicon dioxide, and
wherein the second dielectric material comprises silicon nitride.

6. The method of claim 5, wherein the refractory metal comprises a material selected from the group consisting of aluminum (Al), tungsten (W), and tantalum nitride (TaN).

7. The method of claim 1, further comprising, after said introducing the basic solvent to the bottom walls and side walls of the first and second holes, filling the first and second holes with a third electrically conductive material, resulting in a first via and a second via in the first and second holes, respectively.

8. The method of claim 1,
wherein the structure further includes a third electrically conductive region buried in the dielectric layer,
wherein the third electrically conductive region comprises a fourth electrically conductive material, and
wherein the third electrically conductive region is electrically insulated from the second electrically conductive region.

9. The method of claim 8, further comprising creating a third hole in the dielectric layer resulting in the third electrically conductive region being exposed to the surrounding ambient through the third hole.

10. The method of claim 9, further comprising introducing the basic solvent to bottom walls and side walls of the third hole.

11. The method of claim 10, wherein said introducing the basic solvent to the bottom walls and side walls of the first and second holes and said introducing the basic solvent to the bottom walls and side walls of the third hole are performed simultaneously.

12. The method of claim 11, further comprising, after said introducing the basic solvent to the bottom walls and side walls of the third hole, filling the third hole with a fifth electrically conductive material, resulting in a third via in the third hole.

13. The method of claim 8,
wherein the second electrically conductive region, the third electrically conductive region, and a dielectric portion of the dielectric layer which is sandwiched between the second and third electrically conductive region form a MIM (Metal-Insulator-Metal) capacitor, and
wherein the dielectric portion of the dielectric layer consists of silicon dioxide.

14. A structure formation method, comprising:
providing a structure which includes:
(a) a dielectric layer,
(b) a first electrically conductive region buried in the dielectric layer, wherein the first electrically conductive region comprises copper, and
(c) a second electrically conductive region buried in the dielectric layer, wherein the second electrically conductive region comprises copper and aluminum; then
creating a first hole and a second hole simultaneously in the dielectric layer resulting in the first and second electrically conductive regions being simultaneously exposed to a surrounding ambient through the first and second holes, respectively; and then
introducing a basic solvent to bottom walls and side walls of the first and second holes resulting in a removal of polymer residues on the bottom walls and side walls of the first and second holes, wherein the basic solvent comprises tetramethyl ammonium hydroxide (TMAH).

15. The method of claim 14,
wherein the structure further includes a third electrically conductive region buried in the dielectric layer,
wherein the third electrically conductive region is electrically insulated from the second electrically conductive region,
wherein said creating the first hole and the second hole comprises creating the first hole and creating the second hole,
wherein said creating the first hole comprises:
removing a first dielectric portion of the dielectric layer, and
after said removing the first dielectric portion is performed, removing a second dielectric portion of the dielectric layer resulting in the first hole,
wherein said creating the second hole comprises:
removing a third dielectric portion of the dielectric layer, and
after said removing the third dielectric portion is performed, removing a fourth dielectric portion of the dielectric layer resulting in the second hole,
wherein both the first and third dielectric portions comprise a first dielectric material, and
wherein both the second and fourth dielectric portions comprise a second dielectric material different than the first dielectric material.

16. The method of claim 15,
wherein the second electrically conductive region, the third electrically conductive region, and a dielectric portion of the dielectric layer which is sandwiched between the second electrically conductive region and the third electrically conductive region form a MIM (Metal-Insulator-Metal) capacitor, and
wherein the dielectric portion of the dielectric layer consists of silicon dioxide.

17. A structure, comprising:
(a) a dielectric layer;
(b) a first electrically conductive region buried in the dielectric layer, wherein the first electrically conductive region comprises copper;
(c) a second electrically conductive region buried in the dielectric layer, wherein the second electrically conductive region comprises aluminum and copper; and
(d) a first hole and a second hole in the dielectric layer, wherein the first and second electrically conductive regions are exposed to a surrounding ambient through the first and second holes, respectively.

18. The structure of claim 17, further comprising a third electrically conductive region buried in the dielectric layer, wherein the third electrically conductive region is electrically insulated from the second electrically conductive region.

19. The structure of claim 18,
wherein the second electrically conductive region, the third electrically conductive region, and a dielectric portion of the dielectric layer which is sandwiched between the second electrically conductive region and the third electrically conductive region form a MIM (Metal-Insulator-Metal) capacitor, and
wherein the dielectric portion of the dielectric layer consists of silicon dioxide.

20. The structure of claim 19, further comprising a first copper via, a second copper via, and a third copper via being electrically coupled to the first, second, and third electrically conductive regions, respectively.

21. The structure of claim 17, further comprising a basic solvent on bottom walls and side walls of the first and second holes resulting in a removal of polymer residues on the bottom walls and side walls of the first and second holes,
wherein the refractory metal comprises aluminum.
